(19) United States
(12) Patent Application Publication
(10) Pub. No.: US 2025/0187842 A1
(43) Pub. Date: Jun. 12, 2025

(54) Transport Facility

(71) Applicant: Daifuku Co., Ltd., Osaka-shi (JP)

(72) Inventors: Daisuke Ogawa, Hinocho (JP); Hiroshi Otsuka, Hinocho (JP); Tadashi Nishikawa, Hinocho (JP); Kenshin Hashiguchi, Hinocho (JP); Yuya Hirao, Hinocho (JP); Daichi Tomida, Hinocho (JP); Kosuke Kimura, Hinocho (JP)

(21) Appl. No.: 18/975,745

(22) Filed: Dec. 10, 2024

(30) Foreign Application Priority Data
Dec. 12, 2023 (JP) 2023-209527

(51) Int. Cl. B65G 43/00; B65G 17/12

(52) U.S. Cl. CPC B65G 43/00; B65G 17/12

(57) ABSTRACT

A transport facility includes a transport vehicle that transports a transport article, a movement path along which the transport vehicle moves, a movable object movable separately from the transport vehicle, and a movable object controller that controls the movable object. The movable object includes an information obtainer that obtains path state information indicating a state of the movement path. The movable object obtains the path state information with the information obtainer while moving along the movement path. The movable object controller performs, based on the path state information obtained by the information obtainer, a map generating process of generating map data of the movement path.

### CROSS-REFERENCE TO RELATED APPLICATION

This application claims priority to Japanese Patent Application No. 2023-209527 filed Dec. 12, 2023, the disclosure of which is hereby incorporated by reference in its entirety.

### BACKGROUND OF THE INVENTION

### Field of the Invention

The present invention relates to a transport facility including a transport vehicle that transports a transport article and a movement path on which the transport vehicle moves.

### Description of Related Art

Japanese Unexamined Patent Application Publication No. 2011-166671 (hereafter referred to as JP 2011-166671) describes a transport facility including a transport vehicle (12) that transports a transport article and a movement path (4, 6) on which the transport vehicle (12) moves. Reference signs in parentheses used in describing the background are the reference signs in JP 2011-166671.

In the transport facility described in JP 2011-166671, the transport vehicle (12) includes a storage (32) that stores map data of the movement path (4, 6). The transport vehicle (12) refers to the map data stored in the storage (32) to move along the movement path (4, 6).

The map data described above is to be newly generated in response to any change in the movement path for the transport vehicle. Such map data generation can be complicated, and may be avoided for the operation of the transport facility.

### SUMMARY OF THE INVENTION

One or more aspects described herein are directed to a transport facility in which the map data of the movement path can be easily generated.

In response to the above, a transport facility includes a transport vehicle that transports a transport article, a movement path along which the transport vehicle moves, a movable object movable separately from the transport vehicle, and a movable object controller that controls the movable object. The movable object includes an information obtainer that obtains path state information indicating a state of the movement path. The movable object obtains the path state information with the information obtainer while moving along the movement path. The movable object controller performs, based on the path state information obtained by the information obtainer, a map generating process of generating map data of the movement path.

In this structure, the path state information can be obtained by the information obtainer included in the movable object that moves separately from the transport vehicle. The map data of the movement path can be generated based on the path state information obtained by the information obtainer. As described above, the structure can thus easily generate the map data of the movement path.

### BRIEF DESCRIPTION OF THE DRAWINGS

FIG. 1 is a plan view of a transport facility according to an embodiment.

FIG. 2 is a perspective view of a transport vehicle included in the transport facility according to the embodiment.

FIG. 3 is a block diagram of the transport facility according to the embodiment.

FIG. 4 is a diagram of a movable object obtaining path state information with an information obtainer in an example.

FIG. 5 is a diagram describing a map generating process and a difference extracting process.

### DESCRIPTION OF THE INVENTION

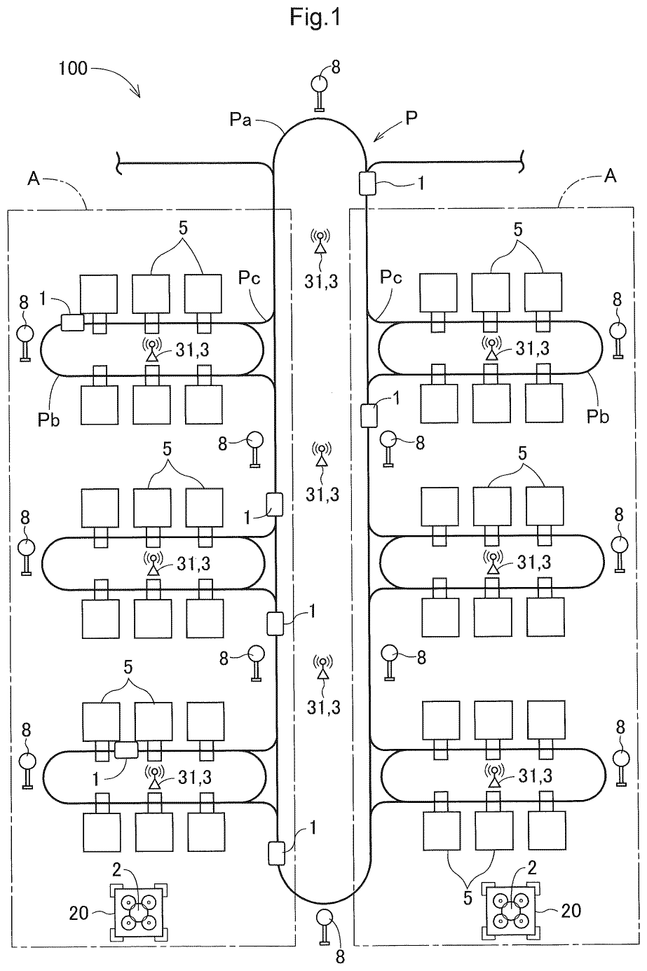

A transport facility 100 according to an embodiment will be described below with reference to the drawings. As shown in FIG. 1, the transport facility 100 includes at least one transport vehicle 1, at least one movable object 2, and a movement path P. In the present embodiment, the transport facility 100 includes multiple transport vehicles 1 and multiple movable objects 2.

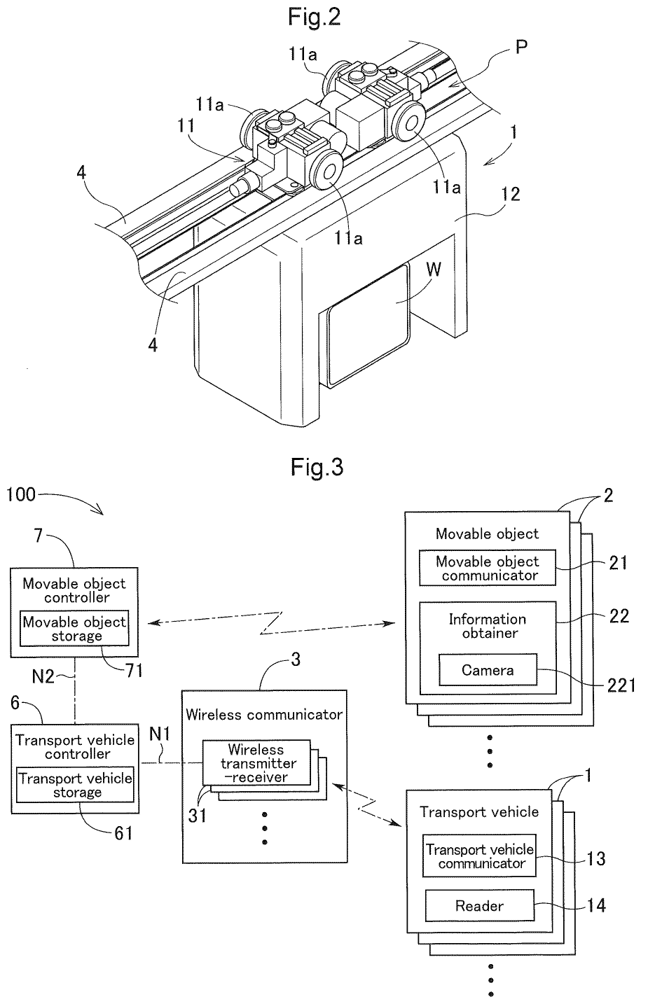

Each transport vehicle 1 transports a transport article W (refer to FIG. 2). The transport article W is, for example, a front opening unified pod (FOUP) containing semiconductor wafers.

The movement path P is a path on which the transport vehicles 1 move. In other words, the transport vehicles 1 transports transport articles W along the movement path P.

In the present embodiment, the movement path P includes a looped primary path Pa, multiple looped secondary paths Pb each extending through multiple processing devices 5, and multiple connecting paths Pc connecting the primary path Pa and the secondary paths Pb.

Each processing device 5 performs predetermined processing on the transport article W (or an object contained in the transport article W). For example, the transport vehicle 1 loads the transport article W to be processed in the processing device 5 into the processing device 5 and unloads the transport article W processed in the processing device 5 from the processing device 5.

The movable objects 2 move separately from the transport vehicles 1. In the present embodiment, the movable objects 2 are unmanned aerial vehicles. In other words, the movable objects 2 are movable on a path different from the movement path P. In the present example, each movable object 2 flies within a preset flight area A. In the present example, the transport facility 100 includes at least one flight area A to allow at least one movable object 2 to correspond to one flight area A. In the present example, the transport facility 100 includes standby units 20 at which the movable objects 2 as unmanned aerial vehicles depart, land, or are on standby after landing. The standby units 20 may include chargers for charging the batteries in the movable objects 2.

In the present embodiment, as shown in FIG. 2, the movement path P includes rails 4. The transport vehicles 1 travel on the rails 4. In the example shown in FIG. 2, the rails 4 as a pair are horizontally spaced from each other and hung from the ceiling. In other words, in the present example, the transport vehicles 1 are ceiling-hung transport vehicles.

In the present embodiment, each transport vehicle 1 includes a traveler 11 that travels on the rails 4, and a body 12 connected to the traveler 11.

The traveler 11 includes travel wheels 11a that roll on the travel surfaces (upper surfaces in this example) of the rails 4. The travel wheels 11a are rotated by a travel driver (not shown), or for example, by an electric motor such as a servomotor.

The body 12 is disposed below the rails 4 and hung from the traveler 11. The body 12 includes a support and a lift (not shown). The support is supported on the traveler 11 to be lifted and lowered with respect to the traveler 11 and suspends the transport article W. The lift lifts and lowers the support.

In the example shown in FIG. 2, the transport vehicle 1 is a ceiling-hung transport vehicle that travels along the rails 4 hung from the ceiling. However, the transport vehicle 1 may be of any other type. For example, the transport vehicle 1 may be a tracked transport vehicle that travels along rails on a floor surface. The transport vehicle 1 may also be a trackless transport vehicle such as an automated guided vehicle (AGV) or an autonomous mobile robot (AMR). The transport vehicle 1 being a trackless transport vehicle travels along a virtual movement path P, instead of a physical movement path P that includes rails or other members. In this case, the movement path P is virtually defined to connect multiple detectable members such as two-dimensional codes or radio frequency (RF) tags installed on the floor surface. The movement path P may also be virtually defined based on a route calculated using recognition results of the surrounding environment, without such detectable members on the floor surface.

As shown in FIG. 3, the transport facility 100 includes a movable object controller 7. In the present embodiment, the transport facility 100 further includes a wireless communicator 3 and a transport vehicle controller 6.

The wireless communicator 3 performs wireless communication with the transport vehicles 1. In the present embodiment, the wireless communicator 3 includes multiple wireless transmitter-receivers 31 arranged in a distributed manner (refer also to FIG. 1). Each wireless transmitter-receiver 31 functions as an access point in wireless communication. In the present application, wireless communication refers to communication performed under a predetermined wireless communication standard, such as Wi-Fi (registered trademark), Bluetooth (registered trademark), or ZigBee (registered trademark).

In the present embodiment, each transport vehicle 1 further includes a transport vehicle communicator 13 that performs wireless communication with the wireless communicator 3.

The transport vehicle communicator 13 functions as a wireless station that performs wireless communication with the wireless transmitter-receivers 31. The transport vehicle communicator 13 establishes a communication link with a wireless transmitter-receiver 31 (e.g., a wireless transmitter-receiver 31 having the highest radio field intensity) selected from the multiple wireless transmitter-receivers 31. The transport vehicle communicator 13 is then connected to and communicates with the selected wireless transmitter-receiver 31. While traveling, the transport vehicle 1 switches the wireless transmitter-receiver 31 with which the transport vehicle communicator 13 in the transport vehicle 1 establishes a communication link (performs roaming). For example, roaming is performed in response to the radio field intensity received from the connected wireless transmitter-receiver 31 being lower than or equal to a predetermined value.

The transport vehicle controller 6 controls the transport vehicles 1. In the present embodiment, the transport vehicle controller 6 is connected to the multiple wireless transmitter-receivers 31 in the wireless communicator 3 with a first communication network N1. The transport vehicle controller 6 communicates with the transport vehicle communicator 13 in each transport vehicle 1 through the corresponding wireless transmitter-receiver 31 to control the transport vehicle 1. The first communication network N1 may be wired, wireless, or a combination of both.

In the present embodiment, each transport vehicle 1 includes a controller (not shown) for controlling its operations (e.g., traveling and transfer of the transport article W). The transport vehicle controller 6 communicates with the transport vehicle communicator 13 in each transport vehicle 1 through the corresponding wireless transmitter-receiver 31 to provide commands for the above operations to the controller in the transport vehicle 1.

In the present embodiment, as shown in FIG. 1, information holders 8 are installed at specific locations along the movement path P (the rails 4 in this example). The information holders 8 hold predetermined information. In the present embodiment, the information held by the information holders 8 includes position information indicating positions along the rails 4.

Each information holder 8 includes, for example, a one-dimensional code, a two-dimensional code, or a radio frequency (RF) tag. Each information holder 8 may be disposed on a surface of the rails 4 or may be supported on a predetermined support member near the rails 4. In the example shown in FIG. 1, the information holders 8 are supported by the respective multiple support members at multiple locations along the movement path P.

As shown in FIG. 3, each transport vehicle 1 in the present embodiment further includes a reader 14. The reader 14 reads information held by the information holders 8 (the position information indicating the positions along the rails 4 in this example). In the present embodiment, each transport vehicle 1 reads the position information with the reader 14 while traveling on the rails 4 to identify the position of the transport vehicle 1.

The movable object controller 7 controls the movable objects 2. In the present embodiment, each movable object 2 includes a movable object communicator 21. The movable object communicator 21 performs wireless communication with the movable object controller 7. The movable object communicator 21 may perform wireless communication with at least one of the transport vehicle communicator 13 or the corresponding wireless transmitter-receiver 31.

In the present embodiment, each movable object 2 includes a controller (not shown) for controlling its operations (e.g., flying). The movable object controller 7 performs wireless communication with the movable object communicator 21 in each movable object 2 to provide commands for the above operations to the controller in the movable object 2. In the present embodiment, each movable object 2 identifies its current position.

As shown in FIG. 3, each movable object 2 includes an information obtainer 22. The information obtainer 22 obtains path state information i. The path state information i indicates the state of the movement path P.

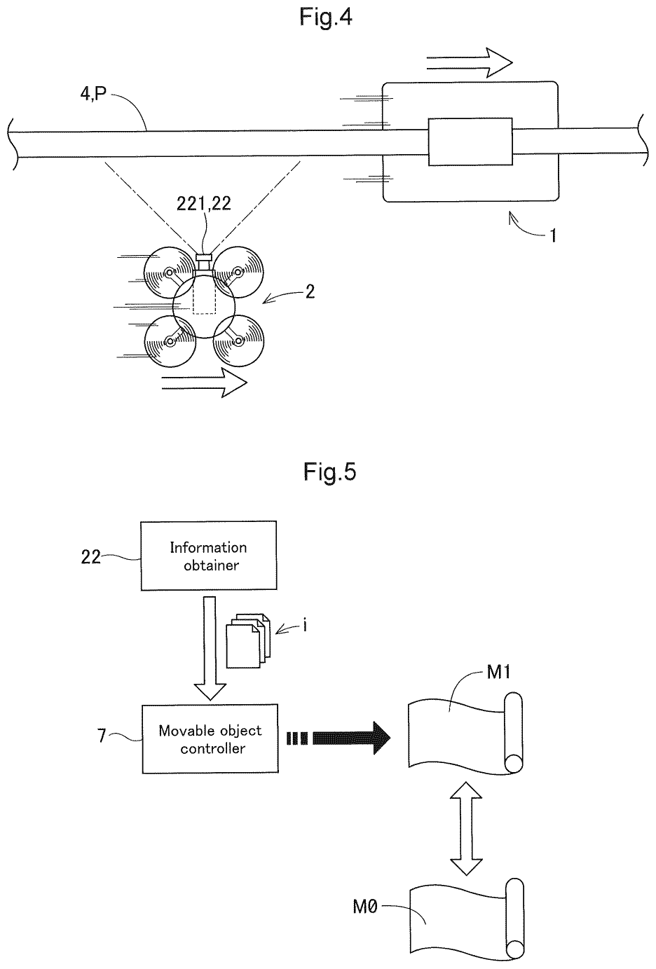

As shown in FIG. 4, each movable object 2 obtains the path state information i with the information obtainer 22 while moving along the movement path P. In the example shown in FIG. 4, during the operation of the transport facility 100, the movable object 2 as an unmanned aerial vehicle obtains the path state information i with the information obtainer 22 while flying along the movement path P without interfering with the transport vehicle 1 traveling on the rails 4.

In the present embodiment, the information obtainer 22 includes a camera 221 for capturing the movement path P (the rails 4 in this example). The camera 221 may take images at a constant interval (based on time or a travel distance of the movable object 2) or may take videos. The camera 221 may capture the movement path P alone or capture the movement path P and its surrounding area. In the present example, the information holders 8 are arranged on lower surfaces of the rails 4. The camera 221 captures the rails 4 from below. When the movable objects 2 are unmanned aerial vehicles, the camera 221 included in each movable object 2 may capture the movement path P in multiple directions.

In the present embodiment, the camera 221 obtains, as the path state information i, at least one of the shape of each part of the movement path P (e.g., the shape of a linear part, a curve, a junction, or a branch of the rails 4), the structure of each part of the movement path P (e.g., the number of rails 4, whether a feed line is disposed on the rails 4 to feed power to the transport vehicles 1, or whether a lift assembly is disposed on the rails 4 to lift or lower the transport vehicles 1), the positions of the information holders 8, or the information held by each information holder 8 (the position information indicating the position along the rails 4 in this example).

As shown in FIG. 5, the movable object controller 7 performs a map generating process of generating, based on the path state information i obtained by the information obtainer 22, generated map data M1 that is map data of the movement path P. In the example shown in FIG. 3, the movable object controller 7 includes a movable object storage 71. The generated map data M1 is stored in the movable object storage 71. In the present example, the movable object controller 7 obtains, from each movable object 2, the position information indicating the current position of the movable object 2. The position information is then stored into the movable object storage 71.

In the present application, the map data of the movement path P includes various items of information (e.g., information obtained as the path state information i) reflected on the shape and the structure of the movement path P. In the present embodiment, the map data of the movement path P includes the positions of the processing devices 5, the positions of the devices (e.g., a traffic signal and a crossing gate) for traffic control of the transport vehicles 1, and the positions of the wireless transmitter-receivers 31.

In the present embodiment, at least one of the transport vehicles 1 or the transport vehicle controller 6 includes reference map data M0. The reference map data M0 is map data of the movement path P to be referred to for the movement of the transport vehicles 1. In the present embodiment, the reference map data M0 is referred to by the transport vehicle controller 6 to generate commands for the transport vehicles 1. In the example shown in FIG. 3, the transport vehicle controller 6 includes a transport vehicle storage 61. The reference map data M0 is stored in the transport vehicle storage 61. More specifically, in the present example, the transport vehicle controller 6 includes the reference map data M0. The transport vehicle controller 6 in the present example obtains, from each transport vehicle 1, the position information indicating the current position of the transport vehicle 1. The position information is then stored into the transport vehicle storage 61.

As shown in FIG. 3, the transport vehicle controller 6 and the movable object controller 7 in the present embodiment are connected to each other with a second communication network N2. This allows the transport vehicle controller 6 and the movable object controller 7 in the present embodiment to refer to the data of the other and transmit and receive data to and from each other. The second communication network N2 may be wired, wireless, or a combination of both.

As shown in FIG. 5, at least one of the transport vehicle controller 6 or the movable object controller 7 in the present embodiment compares the generated map data M1 with the reference map data M0, and performs a difference extracting process of extracting any difference between the two sets of data. In the present example, the transport vehicle controller 6 obtains, from the movable object controller 7, the generated map data M1 stored in the movable object storage 71, and uses the generated map data M1 and the reference map data M0 stored in the transport vehicle storage 61 to perform the difference extracting process. In the difference extracting process, differences in data format and items between the generated map data M1 and the reference map data M0 are not extracted, but differences in materials for the same data format and items are extracted.

In the present embodiment, at least one of the transport vehicle controller 6 or the movable object controller 7 performs a map correcting process of correcting the reference map data M0 based on the differences extracted in the difference extracting process. In the map correcting process, the reference map data M0 is corrected to match the data in the reference map data M0 extracted as the differences with the corresponding data in the generated map data M1. In the present example, the transport vehicle controller 6 corrects the reference map data M0 and updates the reference map data M0 stored in the transport vehicle storage 61 to the corrected reference map data M0.

### Other Embodiments

(1) In the above embodiment, the movable objects 2 are unmanned aerial vehicles that are movable on a path different from the movement path P for the transport vehicles 1. In some embodiments, the movable objects 2 may move on the movement path P for the transport vehicles 1 (or may be, for example, vehicles that travel on the rails 4). Such movable objects 2 may transport, similarly to the transport vehicles 1, transport articles W in normal operations or may be dedicated to collecting the path state information i without transporting transport articles W.

(2) In the above embodiment, the movable object controller 7 provides commands to the controller in each movable object 2. In some embodiments, for example, the movable object controller 7 may be incorporated in each of the multiple movable objects 2 to allow the corresponding movable object 2 to operate independently of the others or cooperate with the others.

(3) In the above embodiment, the information obtainer 22 includes the camera 221 for capturing the movement path P. In some embodiments, in place of the camera 221, the information obtainer 22 may include, for example, a light detection and ranging (LiDAR) device or a millimeter wave radar.

(4) In the above embodiment, the transport vehicle controller 6 includes the reference map data M0. In some embodiments, instead of the transport vehicle controller 6, the transport vehicles 1 may include the reference map data M0. In some embodiments, both the transport vehicle controller 6 and the transport vehicles 1 may include the reference map data M0.

(5) In the above embodiment, the transport vehicle controller 6 performs the difference extracting process. In some embodiments, instead of the transport vehicle controller 6, the movable object controller 7 may perform the difference extracting process. In some embodiments, both the transport vehicle controller 6 and the movable object controller 7 may perform the difference extracting process. In this structure, when the result of the difference extracting process performed by the transport vehicle controller 6 is different from the result of the difference extracting process performed by the movable object controller 7, the difference extracting process may be performed again, or one of these results may be selected as the result of the difference extracting process.

(6) In the above embodiment, the transport vehicle controller 6 performs the map correcting process. In some embodiments, instead of the transport vehicle controller 6, the movable object controller 7 may perform the map correcting process. In some embodiments, both the transport vehicle controller 6 and the movable object controller 7 may perform the map correcting process. In this structure, when the result of the map correcting process performed by the transport vehicle controller 6 is different from the result of the map correcting process performed by the movable object controller 7, the map correcting process may be performed again, or one of these results may be selected as the result of the map correcting process.

(7) The structure described in each of the above embodiments may be combined with any other structures described in the other embodiments unless any contradiction arises. For other structures as well, the embodiments described herein are merely illustrative in all aspects. Thus, the embodiments described herein may be modified variously as appropriate without departing from the spirit and scope of the disclosure.

### Overview of Present Embodiment

An overview of the transport facility described above is provided below.

A transport facility includes a transport vehicle that transports a transport article, a movement path along which the transport vehicle moves, a movable object movable separately from the transport vehicle, and a movable object controller that controls the movable object. The movable object includes an information obtainer that obtains path state information indicating a state of the movement path. The movable object obtains the path state information with the information obtainer while moving along the movement path. The movable object controller performs, based on the path state information obtained by the information obtainer, a map generating process of generating map data of the movement path.

In this structure, the path state information can be obtained by the information obtainer included in the movable object that moves separately from the transport vehicle. The map data of the movement path can be generated based on the path state information obtained by the information obtainer. As described above, the structure can thus easily generate the map data of the movement path.

The transport facility may further include a transport vehicle controller that controls the transport vehicle.

At least one of the transport vehicle or the transport vehicle controller may include reference map data of the movement path referred to for movement of the transport vehicle.

At least one of the transport vehicle controller or the movable object controller may compare generated map data generated in the map generating process with the reference map data, and perform a difference extracting process of extracting a difference between the generated map data and the reference map data.

In this structure, the generated map data reflecting the actual state of the movement path is used to extract the difference in the reference map data from the actual state. This increases the likelihood of avoiding use of reference map data showing data different from the actual state.

In the above structure, at least one of the transport vehicle controller or the movable object controller may perform a map correcting process of correcting the reference map data based on the difference extracted in the difference extracting process.

This structure can update the reference map data to the latest map data corresponding to the generated map data that reflects the actual state of the movement path.

The information obtainer may include a camera that captures the movement path.

The camera may obtain, as the path state information, at least one of a shape of each part of the movement path, a structure of each part of the movement path, a position of an information holder at a specific location along the movement path, or information held by the information holder.

This structure can appropriately obtain the path state information for generating map data in the map generating process.

The movement path may be a rail.

The transport facility may include, at a specific location on the rail, an information holder holding position information indicating a position along the rail.

The transport vehicle may include a reader that reads the position information held by the information holder. The transport vehicle may read the position information with the reader while traveling on the rail to identify a position of the transport vehicle.

The movable object may be an unmanned aerial vehicle.

The information obtainer may include a camera that captures the rail.

In this structure, the movable object can freely fly around the rail. This allows the camera included in the information obtainer in the movable object to capture the rail in an appropriate direction. Thus, the structure can obtain the path state information for generating map data in the map generating process.

### INDUSTRIAL APPLICABILITY

The technique according to one or more embodiments of the disclosure is applicable to a transport facility including a transport vehicle that transports a transport article and a movement path on which the transport vehicle moves.

What is claimed is:

1. A transport facility, comprising:
a transport vehicle configured to transport a transport article;
a movement path along which the transport vehicle moves;
a movable object movable separately from the transport vehicle; and
a movable object controller configured to control the movable object,
wherein the movable object comprises an information obtainer configured to obtain path state information indicating a state of the movement path, the movable object configured to obtain the path state information with the information obtainer while moving along the movement path, and
wherein the movable object controller is configured to perform, based on the path state information obtained by the information obtainer, a map generating process of generating map data of the movement path.

2. The transport facility according to claim 1, further comprising:
a transport vehicle controller configured to control the transport vehicle,
wherein at least one of the transport vehicle or the transport vehicle controller comprises reference map data of the movement path, and the reference map data is referred to for movement of the transport vehicle, and
wherein at least one of the transport vehicle controller or the movable object controller compares generated map data generated in the map generating process with the reference map data, and performs a difference extracting process of extracting a difference between the generated map data and the reference map data.

3. The transport facility according to claim 2, wherein:
at least one of the transport vehicle controller or the movable object controller performs a map correcting process of correcting the reference map data based on the difference extracted in the difference extracting process.

4. The transport facility according to claim 1, wherein:
the information obtainer comprises a camera configured to capture the movement path, and
the camera obtains, as the path state information, at least one of a shape of each part of the movement path, a structure of each part of the movement path, a position of an information holder at a specific location along the movement path, or information held by the information holder.

5. The transport facility according to claim 1, wherein:
the movement path is a rail,
the transport facility comprises, at a specific location on the rail, an information holder holding position information indicating a position along the rail,
the transport vehicle comprises a reader configured to read the position information held by the information holder, and the transport vehicle reads the position information with the reader while traveling on the rail to identify a position of the transport vehicle,
the movable object is an unmanned aerial vehicle, and
the information obtainer comprises a camera configured to capture the rail.
